(19) United States
(12) Patent Application Publication
(10) Pub. No.: US 2007/0048889 A1
(43) Pub. Date: Mar. 1, 2007

(54) METHOD OF FORMING A PIEZORESISTIVE DEVICE CAPABLE OF SELECTING STANDARDS AND METHOD OF FORMING A CIRCUIT LAYOUT CAPABLE OF SELECTING SUB-CIRCUIT LAYOUTS

(76) Inventors: Hung-Yi Lin, Tao-Yuan Hsien (TW); Pin-Ting Liu, Kao-Hsiung Hsien (TW); Tsung-Hsun Tsai, Tai-Nan City (TW)

Correspondence Address: NORTH AMERICA INTELLECTUAL PROPERTY CORPORATION, P.O. BOX 506, MERRIFIELD, VA, 22116, US

(21) Appl. No.: 11/164,331

(22) Filed: Nov. 18, 2005

(30) Foreign Application Priority Data
Aug. 23, 2005 (TW) 094128781

(51) Int. Cl. H01L 21/00

(52) U.S. Cl. 438/53

(57) ABSTRACT

A wafer is provided, and a circuit layout including a first piezoresistive device layout and a second piezoresistive device layout is formed on the front surface of the wafer. The first piezoresistive device layout includes a plurality of first nodes and the second piezoresistive device layout includes a plurality of second nodes. Subsequently, a dielectric layer is formed on the circuit layout, and the dielectric layer is patterned to expose either the first nodes or the second nodes. Thereafter, a connection pattern is formed on the dielectric layer to electrically connect the first nodes or the second nodes.

### BACKGROUND OF THE INVENTION

1. Field of the Invention

The present invention relates to a method of forming a circuit layout capable of selecting sub-circuit layouts, and more particularly, to a method of forming a piezoresistive device capable of selecting a piezoresistive device of a predetermined standard when forming a connection pattern by misaligning the layouts of piezoresistive devices of different standards.

2. Description of the Prior Art

As the development of micro-electromechanical system (MEMS) technologies progresses, types of micro-electromechanical devices such as micro pressure sensors, micro acceleration sensors, and microphone devices have been widely applied in every field. Among the various kinds of micro pressure sensors, the piezoresistive pressure sensor of high-fidelity and high-stability is more extensively used.

The piezoresistive pressure sensor achieves its pressure sensing function by using the piezoresistors, which transform the variation of the stress values into the variation of the resistance values. To assure the high fidelity of the piezoresistive pressure sensor, the piezoresistors are formed on the diaphragm, such that it can enhance its sensitivity by enlarging the variation of the stress values. Meanwhile, the piezoresistors themselves are connected in a Wheatstone bridge arrangement to enlarge the variation of the voltage values transformed from the variation of the resistance value. Therefore the forming of the piezoresistive pressure sensors can be divided into a front surface process for forming the circuit layout and a back surface process for forming the diaphragm. The front surface process generally needs 5 masks while the back surface process needs only 1. Thus the front surface process not only has a much higher cost in the whole fabricating processes, but also has a longer production cycle.

Please refer to FIGS. 1-4. FIGS. 1-4 illustrate the conventional front surface process for forming the piezoresistive pressure sensors. As illustrated in FIG. 1, a wafer 10 is provided, and a first mask is used to define the alignment marks (not shown) in the front surface of the wafer 10. Then an etching process is performed to form the alignment marks in the front surface of the wafer 10 for the follow-up processes. After forming the alignment marks, a second mask is used to define the positions of the piezoresistors in the front surface of the wafer 10. Then a first ion implanting process is performed to form the piezoresistors 12 in the front surface of the wafer 10. As illustrated in FIG. 2, a third mask is used to define the positions of the conducting wires and the nodes of the piezoresistors 12 in the front surface of the wafer 10. Then a second ion implanting process is performed to form the conducting wires 14 and the nodes 16 in the front surface of the wafer 10.

As illustrated in FIG. 3, a dielectric layer 18 is deposited on the front surface of wafer 10, and a fourth mask is used to define the positions of the contact holes in the surface of the dielectric layer 18. Thereafter, an etching process is performed to form a plurality of contact holes 20 which expose the nodes (not shown in FIG. 3) in the dielectric layer 18. Finally, as illustrated in FIG. 4, a fifth mask is used with a depositing and an etching processes to form a connection pattern 22 in the surface of the dielectric layer 18. The connection pattern 22 is electrically connected to the nodes (not shown in FIG. 4) through the contact hole 20 thus the piezoresistors (not shown in FIG. 4) are formed in the Wheatstone bridge arrangement and the circuit layout of the piezoresistive pressure sensor is constructed.

It is appreciated that along with the different requirements in the pressure sensing range of the pressure sensor products, there are many size standards for the piezoresistive pressure sensors. Once the size standard changes, the aforementioned second to fifth masks have to be replaced, so that the cost for fabricating the piezoresistive pressure sensors is increased.

As mentioned above, it is obvious that the conventional method of forming the piezoresistive pressure sensor device has many drawbacks and needs to be improved. Therefore the applicant herein provides the present invention according to his experience in the MEMS manufacturing.

### SUMMARY OF THE INVENTION

It is therefore a primary object of the claimed invention to provide a method of forming a piezoresistive device capable of selecting standards to overcome the aforementioned problems.

According to the claimed invention, a method of forming a piezoresistive device capable of selecting standards comprises providing a wafer, the wafer comprising a front surface; forming a circuit layout in the front surface of the wafer, the circuit layout comprising at least a first piezoresistive device layout and at least a second piezoresistive device layout, and the first piezoresistive device layout and the second piezoresistive device layout comprising a plurality of first nodes and a plurality of second nodes respectively; forming at least a dielectric layer on the circuit layout and patterning the dielectric layer to selectively expose either the first nodes or the second nodes; and forming a connection pattern on the dielectric layer, the connection pattern being electrically connected to either the first nodes or the second nodes.

To achieve the aforementioned object, a method of forming piezoresistive devices capable of selecting sub-circuit layouts according to the claimed invention comprises providing a wafer; forming a circuit layout in the wafer, and the circuit layout comprising at least a first sub-circuit layout and at least a second sub-circuit layout, the first sub-circuit layout and the second sub-circuit layout comprising a plurality of first nodes and a plurality of second nodes respectively; forming at least a dielectric layer on the circuit layout and patterning the dielectric layer to selectively expose either the first nodes or the second nodes; and forming a connection pattern on the dielectric layer, the connection pattern being electrically connected to either the first nodes or the second nodes.

Because the method provided in the claimed invention forms sub-circuit layouts of different standards in the wafer, then selects connection patterns corresponding to the different sub-circuit layouts to enable the selected sub-circuit layouts, it can save on the total number of masks used in the processes and can thereby reduce the manufacturing cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 are schematic diagrams of a method of forming a piezoresistive pressure sensor device in the prior art.

FIGS. 5-10 are schematic diagrams of a method of forming a piezoresistive device capable of selecting standards according to the preferred embodiment of the present invention.

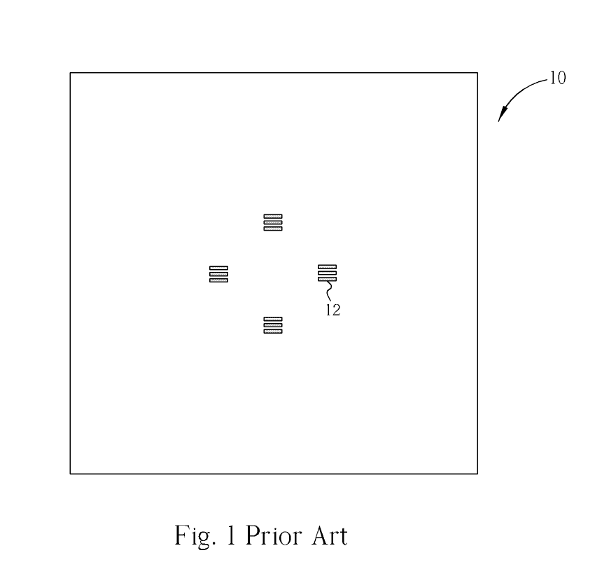

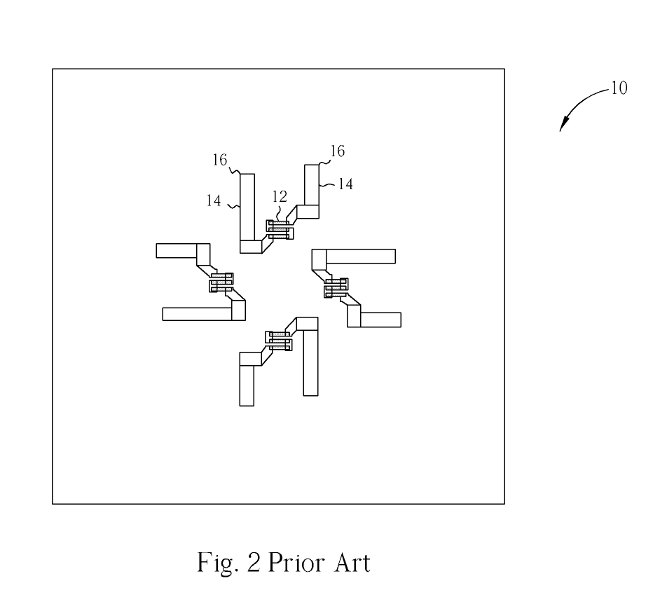

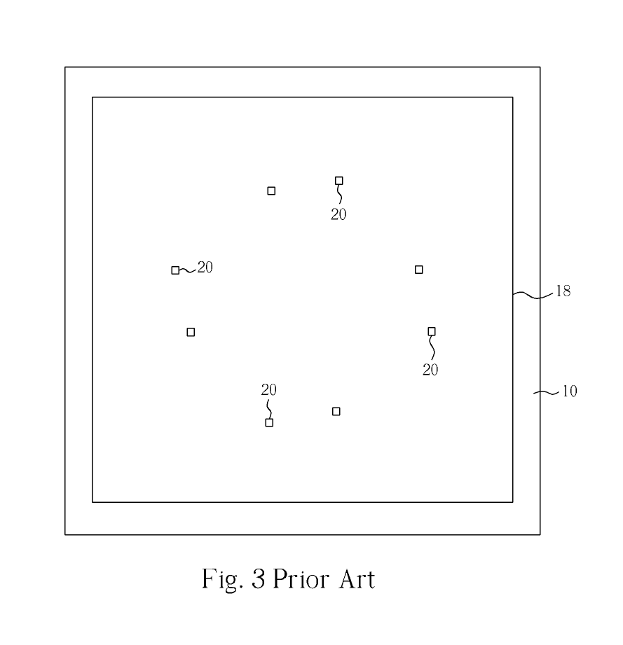

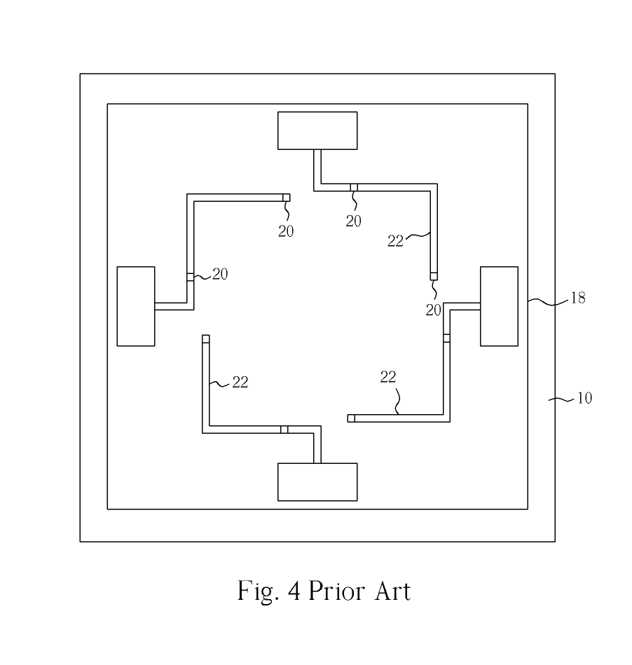

### DETAILED DESCRIPTION

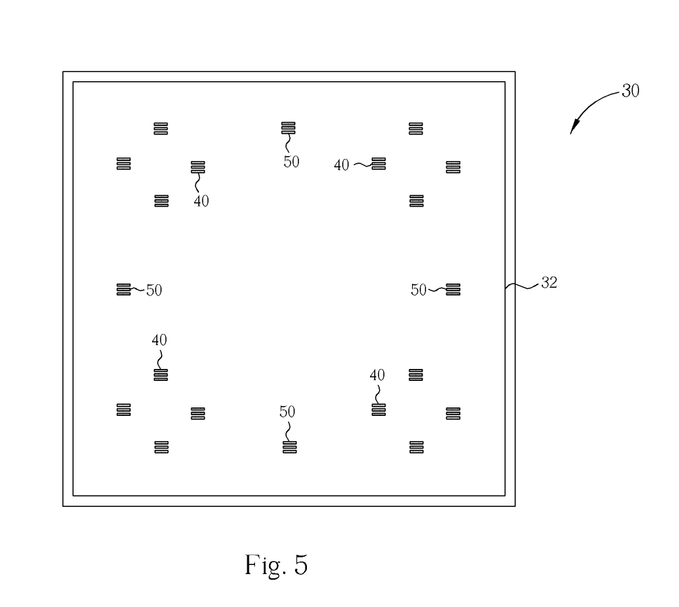

Please refer to FIGS. 5-10, which are the schematic diagrams of a method of forming a piezoresistive device capable of selecting standards according to the preferred embodiment of the present invention. This embodiment uses the front surface process of forming piezoresistive pressure sensor devices as an example to illustrate the method of forming piezoresistive devices capable of selecting standards in the present invention. As illustrated in FIG. 5, a wafer 30 such as a silicon wafer or a silicon on insulator (SOI) wafer is firstly provided, and at least a cleaning process is performed to assure the cleanliness of the wafer 30. Then a thermal oxidation process or a depositing process is used to form a dielectric layer 32, such as a silicon oxide layer, in the front surface of the wafer 30 to prevent the front surface of the wafer 30 from damaging in the follow-up ion implanting processes. Thereafter, a first mask is used to define the positions of alignment marks (not shown) on the surface of the dielectric layer 32 and an etching process is performed in the surface of the dielectric layer 32 to form the alignment marks for the follow-up processes. After forming the alignment marks, a second mask is used to define the positions of the piezoresistors on the front surface of the wafer 30, and a first ion implanting process which implants boron or phosphorous ions into the front surface of the wafer 30 is performed to form a plurality of first piezoresistors 40 and a plurality of second piezoresistors 50 respectively. The first piezoresistors 40 are used to form the piezoresistive pressure sensors having a small size and the second piezoresistors 50 are used to form the piezoresistive pressure sensors having a large size.

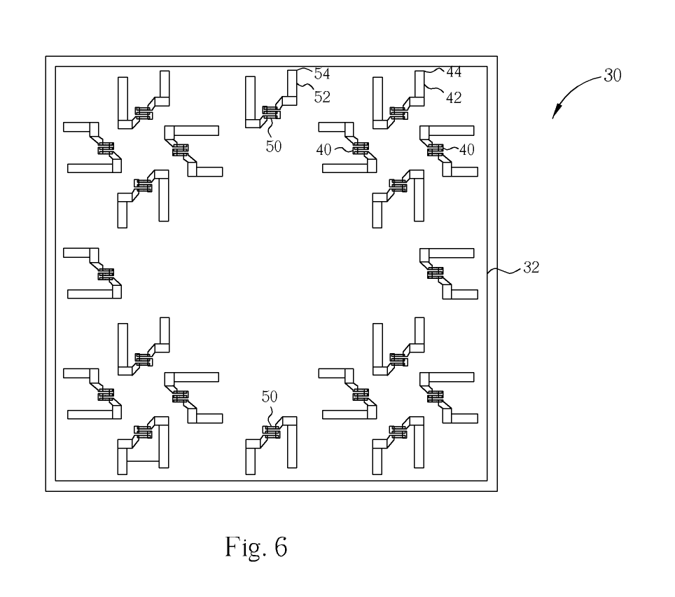

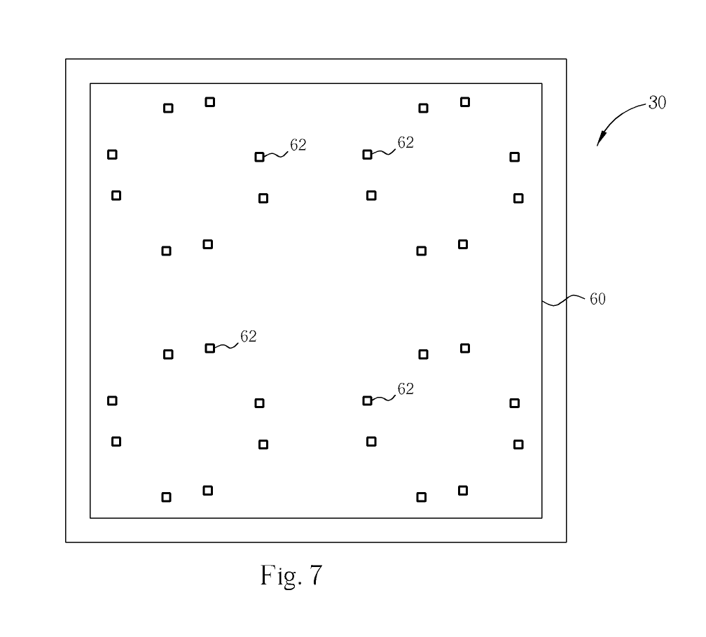

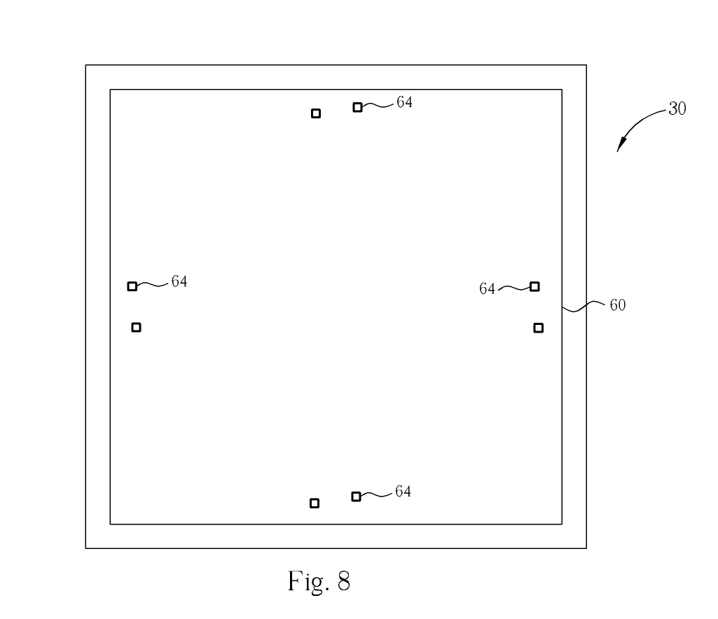

As illustrated in FIG. 6, a third mask is used with a second ion implanting process to define first conducting wires 42 and first nodes 44 of the first piezoresistors 40, and second conducting wires 52 and second nodes 54 of the second piezoresistors 50. In this embodiment, the first ion implanting process is used to form the piezoresistors and the second ion implanting process is used to form the conducting wires and the nodes, but the implementation order is not limited to this and can be alternated according to specific requirements. As illustrated in FIG. 7, the dielectric layer 32 is removed and another dielectric layer 60 is formed in the front surface of the wafer 30. The dielectric layer 60 can be a silicon oxide layer, a silicon nitride layer, or a combination of silicon oxide and silicon nitride. Then a fourth mask is used with an etching process to form a plurality of contact holes in the dielectric layer 60. It is appreciated that if the desired piezoresistive pressure sensors are the piezoresistive pressure sensors having a small size, the contact holes 62 are formed in the dielectric layer 62 and the first nodes 44 are exposed as illustrated in FIG. 7. On the contrary, if the desired piezoresistive pressure sensors are the piezoresistive pressure sensors having a large size, the contact holes 64 are formed in the dielectric layer 60 and the second nodes 54 are exposed as illustrated in FIG. 8.

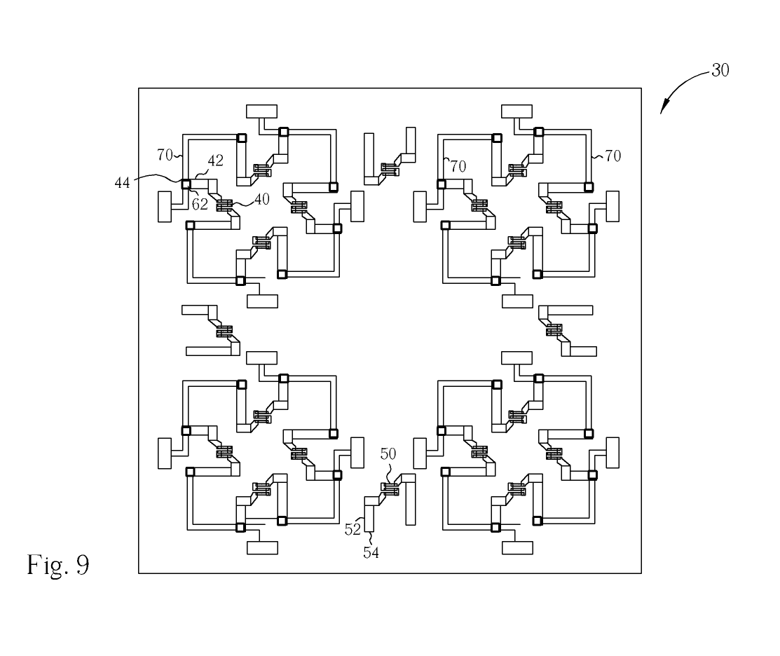

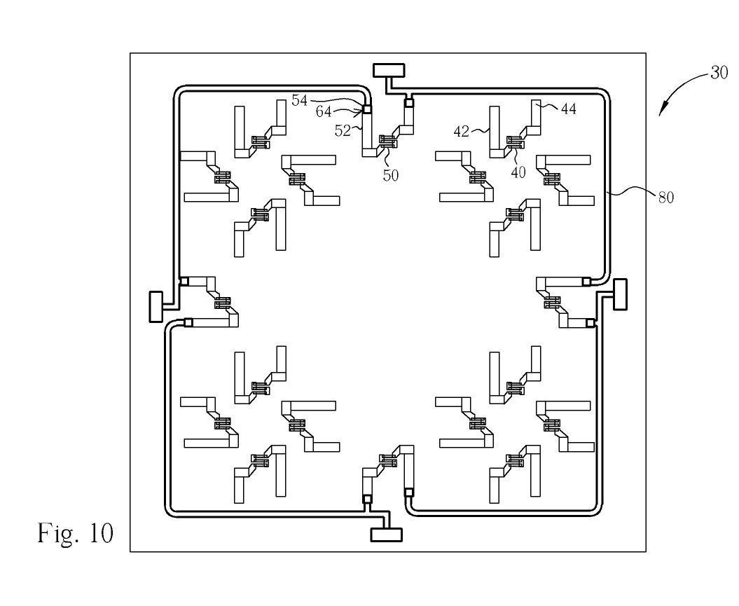

Thereafter, a fifth mask is used with a depositing process and an etching process to form a connection pattern in the dielectric layer 60. If the desired piezoresistive pressure sensors are the piezoresistive pressure sensors having the small size, the connection pattern 70 is formed as illustrated in FIG. 9. FIG. 9 shows the circuit layouts of the piezoresistive pressure sensors having the small size. For detailing the characteristics of the present invention, FIG. 9 illustrates the wafer with the dielectric layer 60 omitted. As illustrated in FIG. 9, the connection pattern 70 is electrically connected to the first nodes 44 through the contact holes 62, and then four small size piezoresistive pressure sensors are formed. The second piezoresistor 50, the second conducting wire 52, and the second nodes 54 are misaligned among the small size piezoresistive pressure sensors, but not electrically connected to connection pattern 70, therefore they do not work. On the other hand, if the desired piezoresistive pressure sensors are the piezoresistive pressure sensors having the large size, the connection pattern 80 is formed as illustrated in FIG. 10. FIG. 10 shows the circuit layouts of the piezoresistive pressure sensors having the large size. As with FIG. 9, the dielectric layer 60 is omitted from FIG. 10. As illustrated in FIG. 10, connection pattern 80 is electrically connected to the second nodes 54 through the contact holes 64 then one large size piezoresistive pressure sensor is formed. The first piezoresistors 40, the first conducting wires 42, and the first nodes 44 are misaligned among the second piezoresistors 50, the second conducting wires 52, and the second nodes 54, but not electrically connected to connection pattern 80, therefore they do not work.

The abovementioned steps are the front surface process for the piezoresistive devices. The back surface process and the packaging process will be performed after completing the front surface process. However, the back surface process and the packaging process are not the point in this invention, thus a further description is hereby omitted.

As mentioned above, the method of forming piezoresistive devices capable of selecting standards in the present invention simultaneously defines the piezoresistive pressure sensors having the small size, the piezoresistors, the conducting wires, and the nodes of the piezoresistive pressure sensors having the large size on the wafer by the second and the third masks, and simultaneously forms the piezoresistive pressure sensors having a small or large size as desired by selecting the fourth and the fifth masks. In other words, the method provided in the invention will not reduce the integration, furthermore, by replacing only two masks it can form the piezoresistive pressure sensor devices in desired size standards if the standard of the piezoresistive pressure sensors changes. Compared with the prior art, which needs to replace four masks to form the piezoresistive pressure sensors in the desired size standards, the method provided by the invention can substantially reduce the cost and shorten the lead time for the developed products.

Furthermore, the method provided in this invention is not limited in forming the piezoresistive pressure sensors. It also can be applied in forming other devices such as piezoresistive acceleration sensors, piezoresistive microphone devices, or in forming circuit layouts of other kinds of devices. For example, the method in the present invention can be applied in forming a circuit layout comprising a first sub-circuit layout and a second sub-circuit layout on a wafer. The first sub-circuit layout and the second sub-circuit layout are used to form devices of different standards. The first sub-circuit layout and the second sub-circuit layout are formed in misaligned layouts in the same layer so that when forming the contact holes and the connection pattern in the follow-up processes, either the first sub-circuit layout or the second sub-circuit layout is selected to electrically connected to be enabled (such as the first sub-circuit layout) and the other sub-circuit layout (such as the second sub-circuit layout) will not work. In addition, in the condition that the positions of the nodes of the first sub-circuit layout are not overlapped with the positions of the nodes of the second sub-circuit layout, the first sub-circuit layout and the second sub-circuit layout can be in different layers.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a piezoresistive device capable of selecting standards, comprising:
providing a wafer, the wafer comprising a front surface;
forming a circuit layout in the front surface of the wafer, the circuit layout comprising at least a first piezoresistive device layout and at least a second piezoresistive device layout, and the first piezoresistive device layout and the second piezoresistive device layout comprising a plurality of first nodes and a plurality of second nodes respectively;
forming at least a dielectric layer on the circuit layout and patterning the dielectric layer to selectively expose either the first nodes or the second nodes; and
forming a connection pattern on the dielectric layer, the connection pattern being electrically connected to either the first nodes or the second nodes.

2. The method of claim 1, wherein the first piezoresistive device layout and the second piezoresistive device layout are formed in the same layer in the wafer.

3. The method of claim 1, wherein the first piezoresistive device layout and the second piezoresistive device layout are misaligned.

4. The method of claim 1, wherein the first piezoresistive device layout and the second piezoresistive device layout are used to define piezoresistive devices of different sizes.

5. The method of claim 1, wherein the steps of forming the first piezoresistive device layout and the second piezoresistive device layout comprise:
performing a first ion implanting process to form a plurality of first piezoresistors and a plurality of second piezoresistors in the wafer; and
performing a second ion implanting process to form the first nodes and the second nodes in the wafer.

6. The method of claim 1, wherein the first nodes or the second nodes are selectively exposed by forming a plurality of contact holes.

7. The method of claim 1, wherein the piezoresistive device comprises a piezoresistive pressure sensor, a piezoresistive acceleration sensor, or a piezoresistive microphone device.

8. A method of forming a circuit layout capable of selecting sub-circuit layouts, comprising:
providing a wafer;
forming a circuit layout in the wafer, the circuit layout comprising at least a first sub-circuit layout and a second sub-circuit layout, and the first sub-circuit layout and the second sub-circuit layout comprising a plurality of first nodes and a plurality of second nodes respectively;
forming at least a dielectric layer on the circuit layout, and patterning the dielectric layout to selectively expose either the first nodes or the second nodes; and
forming a connection pattern on the dielectric layer, the connection pattern being electrically connected to either the first nodes or the second nodes.

9. The method of claim 8, wherein the first sub-circuit layout and the second sub-circuit layout are formed in the same layer in the wafer.

10. The method of claim 8, wherein the first sub-circuit layout and the second sub-circuit layout are formed in different layers in the wafer.

11. The method of claim 8, wherein the first sub-circuit layout and the second sub-circuit layout are misaligned.
